(19) United States
(12) Patent Application Publication
(10) Pub. No.: US 2024/0055417 A1
(43) Pub. Date: Feb. 15, 2024

(54) ELECTRONIC PACKAGE STRUCTURE

(71) Applicant: Acer Incorporated, New Taipei City (TW)

(72) Inventors: Yu-Ming Lin, New Taipei City (TW); Wen-Neng Liao, New Taipei City (TW); Cheng-Wen Hsieh, New Taipei City (TW); Kuang-Hua Lin, New Taipei City (TW); Wei-Chin Chen, New Taipei City (TW)

(73) Assignee: Acer Incorporated, New Taipei City (TW)

(21) Appl. No.: 18/447,333

(22) Filed: Aug. 10, 2023

(30) Foreign Application Priority Data
Aug. 12, 2022 (TW) 111130489

(51) Int. Cl. H01L 25/16; H01L 23/367; H01L 23/24

(52) U.S. Cl. CPC H01L 25/165; H01L 23/3675; H01L 23/24

(57) ABSTRACT

Provided is an electronic package structure, including a substrate, a first electronic component disposed on the substrate, at least one second electronic component disposed on the substrate, an insulating film disposed on the second electronic component and the substrate, an insulating glue filled onto the second electronic component and the substrate to cover at least part of the insulating film, a liquid metal disposed on the first electronic component, and a heat-dissipating plate disposed on the first electronic component to squeeze the liquid metal. The insulating film and the insulating glue prevent the overflowing liquid metal from contacting the second electronic component and the substrate.

### CROSS-REFERENCE TO RELATED APPLICATION

This application claims the priority benefit of Taiwan application serial no. 111130489, filed on Aug. 12, 2022. The entirety of the above-mentioned patent application is hereby incorporated by reference herein and made a part of this specification.

### BACKGROUND

### Technical Field

The disclosure relates to an electronic package structure.

### DESCRIPTION OF RELATED ART

As users demand electronic products with more function and faster processing speed, die as the core of any electronic product needs to be equipped with denser components and circuits, which is also the reason why great thermal energy is generated by the die upon operation. Furthermore, since the conventional encapsulant system for coating the die is made of materials with a poor thermal conductivity of only 0.8 Wm-1k-1 (hence the poor heat dissipation efficiency), if the heat generated by the die cannot be dissipated effectively, the die may be damaged, making the product reliability problematic. Therefore, in order to dissipate the heat energy to the outside rapidly, it is a common practice in the industry to dispose a heat-dissipating plate in the semiconductor package. The heat-dissipating plate is generally bonded to the back of the chip by heat-dissipating glue, such that the heat of the die may be dissipated by both the glue and the plate. Furthermore, to have a better heat dissipation effect, the top surface of the heat-dissipating plate is usually exposed to the encapsulant or simply exposed to the atmosphere.

Liquid metal is a low melting point alloy that is liquid at room temperature, or an alloy in the form of solid flakes which becomes liquid when heated to its melting point. Its components are, for example, gallium-indium-tin alloy, indium-bismuth-tin alloy, or indium-bismuth-zinc alloy. Their properties are stable and have excellent thermal and electrical conductivity, and its thermal conductivity and specific heat capacity are much higher than those of conventional silicone grease thermal pastes. For that reason, it replaces the heat-dissipating glue and is used as the heat-conducting agent between the heat source and the heat-dissipating fins.

However, in practical applications, due to its high fluidity (and low viscosity) at room temperature, when liquid metal is used as the heat transfer medium between a die and a heat-dissipating plate, there is often the problem of overflowing liquid metal in the process. When the liquid metal is squeezed by the heat-dissipating plate and overflows to the periphery of the die, it causes short-circuit damage as the liquid metal contacts the surrounding electronic components or (the circuits of) the substrate.

### SUMMARY

The disclosure provides an electronic package structure with a stable heat dissipation mechanism to protect electronic components and circuits therein.

The electronic package structure of the disclosure includes a substrate, a first electronic component, at least one second electronic component, an insulating film, an insulating glue, a liquid metal, and a heat-dissipating plate. The first electronic component and the second electronic component are respectively disposed on the substrate, and the second electronic component is adjacent to the first electronic component. The insulating film is disposed on the second electronic component and the substrate. The insulating glue is disposed on the second electronic component and the substrate, and the insulating glue covers at least part of the insulating film. The liquid metal is disposed on the first electronic component. The heat-dissipating plate is disposed on the first electronic component and squeezes the liquid metal, and the insulating film and the insulating glue prevent the overflowing liquid metal from contacting the second electronic component and the substrate.

Based on the above, in the electronic package structure, the insulating film is disposed on the second electronic component, and then the insulating glue is disposed on the substrate, the second electronic component, and the insulating film, such that the insulating glue covers at least part of the insulating film. Therefore, during the assembly process, as the heat-dissipating plate disposed on the first electronic component squeezes the liquid metal therebetween, the insulating glue and the insulating film are able to protect the second electronic component and the substrate by isolating the overflowing liquid metal. In addition to achieving the heat dissipation effect by utilizing the liquid metal effectively, the structure is also able to protect the substrate (and the circuits thereon) and the second electronic component from short circuit caused by the liquid metal, providing an effective heat dissipation mechanism and/or a protection mechanism.

### BRIEF DESCRIPTION OF THE DRAWING

FIG. 1 is a top view of an electronic package structure according to an embodiment of the disclosure.

FIG. 2 is a cross-sectional view of the electronic package structure of FIG. 1 taken along section line A-A.

FIG. 3 to FIG. 5 are cross-sectional views of electronic package structures according to different embodiments of the disclosure.

### DESCRIPTION OF THE EMBODIMENTS

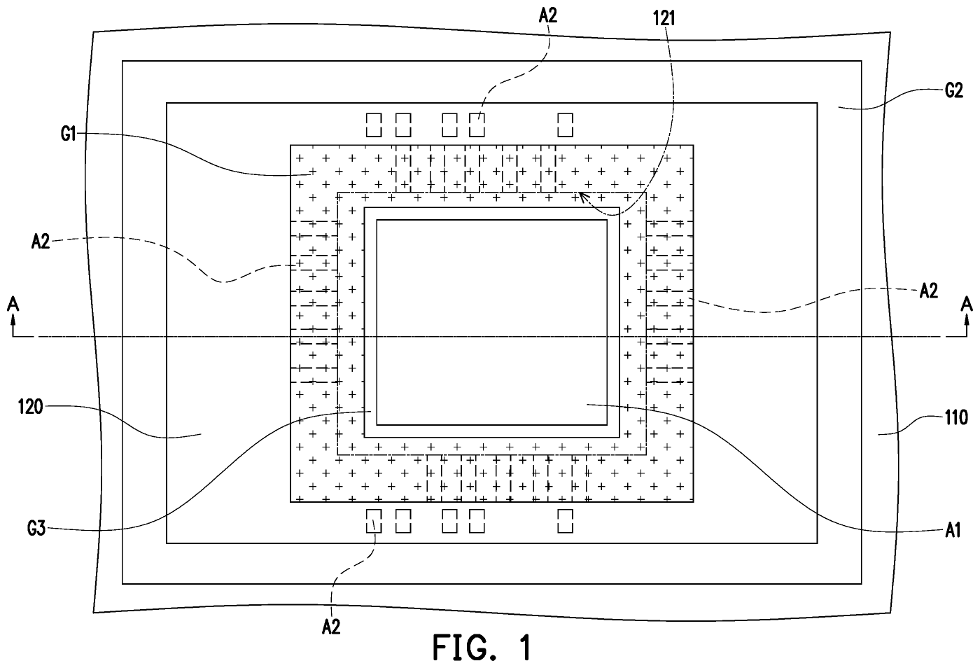

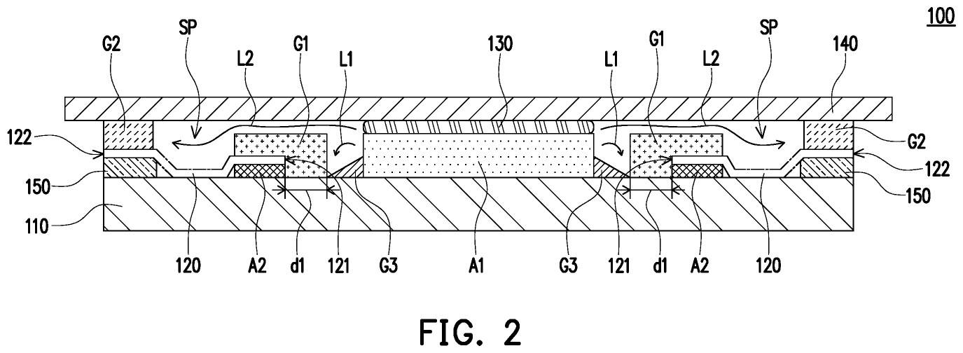

FIG. 1 is a top view of an electronic package structure according to an embodiment of the disclosure. FIG. 2 is a cross-sectional view of the electronic package structure in FIG. 1 along the section line A-A. It should be noted that some components in FIG. 2 are omitted in FIG. 1 to help identify the relationship between components. Please refer to FIG. 1 and FIG. 2 at the same time. The electronic package structure 100 of this embodiment includes a substrate 110, a first electronic component A1, at least one second electronic component (a plurality of second electronic components A2 in this embodiment as an example), an insulating film 120, an insulating glue G1, and a liquid metal 130, and a heat-dissipating plate 140. The first electronic component A1 and the second electronic components A2 are respectively disposed on the substrate 110, and the second electronic components A2 are adjacent to the first electronic component A1. The insulating film 120 is disposed on the second electronic components A2 and the substrate 110. The insulating glue G1 is disposed on the second electronic components A2 and the substrate 110, and the insulating glue G1 covers at least part of the insulating film 120. The heat-dissipating plate 140 is disposed on the first electronic component A1 and squeezes the liquid metal 130 (after the liquid metal 130 is squeezed, the thickness thereof becomes 0.1 mm to 0.2 mm, so as to reduce the thermal resistance). The insulating film 120 and the insulating glue G1 prevent the overflowing liquid metal 130 from contacting the second electronic components A2 and the substrate 110. The thickness shown in the relevant embodiments of the present application is only for the convenience of visual identification and does not represent its actual size and proportion.

As mentioned above, the heat-dissipating plate 140 and the liquid metal 130 in FIG. 2 are omitted in FIG. 1. The first electronic component A1 of the present embodiment is a die to form, for example, a central processing unit (CPU) or a graphics processing unit (GPU). The second electronic components A2 are accessory electronic components, such as a capacitor, disposed with the first electronic component A1. The substrate 110 is, for example, a motherboard carrying the electronic components mentioned above, and a plurality of circuits (not shown) are disposed thereon. The insulating film 120 is, for example, a PET electrical insulating film with a thickness of 0.03 mm. The insulating glue G1 is, for example, a non-conductive polymer gel.

As shown in FIG. 2, in this embodiment, the electronic package structure 100 further includes a retaining wall 150, which is disposed on the substrate 110 and surrounds the first electronic component A1, the second electronic components A2, the insulating film 120, the insulating glue G1, and the liquid metal 130, to form a space SP with the heat-dissipating plate 140 and the substrates 110. The outer edge 122 of the insulating film 120 is sandwiched between the heat-dissipating plate 140 and the retaining wall 150. In other words, the heat-dissipating plate 140, the substrate 110, and the retaining wall 150 (and the insulating glue G2 thereon) form a space SP, such that the first electronic component A1, the second electronic components A2, the insulating film 120, the insulating glue G1, and the liquid metal 130 is in the space SP.

Furthermore, the electronic package structure 100 further includes an insulating glue G2 disposed between the retaining wall 150 and the heat-dissipating plate 140. The outer edge 122 of the insulating film 120 is sandwiched between the insulating glue G2 and the retaining wall 150. Although only the insulating glue G2 may be identified in FIG. 1 (as the retaining wall 150 is under the insulating glue G2 and thus blocked), it is evident that the retaining wall G1 and the insulating glue G2 are equivalent to the side wall structure of the space SP, and they form an a complete space SP that is an integral structure with the heat-dissipating plate 140 and the substrate 110. In addition, the electronic package structure 100 further includes a fixing glue G3 disposed on the substrate 110 and at the periphery of the first electronic component A1 to fix the first electronic component A1 on the substrate 110. In this embodiment, the fixing glue G3 is suitable to be disposed thereon when the first electronic component A1 is packaged on the substrate 110. Here, the fixing glue G3 includes, for example, an epoxy material.

The heat-dissipating plate 140 is, for example, a copper heat-dissipating plate, and a heat sink (such as a heat dissipating fin, fan, or other related heat dissipating device not shown herein) may be added to the other side of the liquid metal 130 to facilitate heat to dissipate from the electronic package structure 100. Meanwhile, in order to prevent the copper heat-dissipating plate and the liquid metal 130 from being corroded by direct contact, the surface of the copper heat-dissipating plate is also provided with an anti-corrosion metal layer as an isolation layer of the copper heat-dissipating plate.

It may be clearly seen from FIG. 2 that there is a gap between the second electronic components A2 and the fixing glue G3. In other words, there is a relative distance dl as shown in FIG. 2. The relative distance dl is less than or equal to 2.0 mm, and the insulating glue G1 partially fills the gap and extends outward to the second electronic components A2. The outline of the insulating film 120 is in a zigzag shape and has an inner edge 121 and an outer edge 122 (marked in FIG. 2). The opening (that is, the inner edge 121) surrounds (and exposes) the first electronic component A1, and the insulating glue G1 covers part of the insulating film 120 adjacent to the inner edge 121. Furthermore, as shown in FIG. 2, the inner edge 121 of the insulating film 120 and part of the insulating glue G1 overlap each other on the second electronic components A2.

During the manufacturing process, in this embodiment, the insulating film 120 is first attached to the substrate 110, the retaining wall 150, and the second electronic components A2, and the insulating glue G1 is then applied to the substrate 110 and the second electronic components A2. The outer edge 122 of the insulating film 120 is sandwiched and fixed by the retaining wall 150 and the heat-dissipating plate 140 (or the retaining wall and the insulating glue G2). After the insulating glue G1 is cured, the inner edge 121 of the insulating film 120 is observably pressed on the second electronic components A2, such that the insulating film 120 may be disposed on the substrate 110 firmly, such that the outer edge 122 or the inner edge 121 does not get flipped over by external force. In another embodiment not illustrated herein, the insulating glues G1 and G2 are used as the insulating glue mentioned above by adopting an uncured thermally conductive gel (H-Putty). However, its thickness needs to be controlled below 1.2 mm to ensure that it contacts (or squeezes) the surrounding structure to form the space SP as required. In other words, once its thickness is larger than 1.2 mm, it is easy to collapse due to its non-curing properties and thus unable to fill the gap. For the insulating glue G2, the collapsed thermal conductive gel would create a gap between the insulating film 120 and the heat-dissipating plate 140, such that the space SP cannot be formed as required.

More importantly, the corresponding configuration of the insulating film 120 and the insulating glue G1 mentioned above is able to reduce the difficulty of the application process effectively. As discussed, there is only a 2.3 mm gap between the fixing glue G3 and the capacitor (the second electronic components A2), so it is not easy to control the application range and dosage of the insulating glue G1 precisely. The prior art merely manages to coat all the second electronic components A2 with the insulating glue G1, which has observable disadvantages such as excessive use of the insulating glue G1 and long application time. In order to reduce the amount of the insulating glue G1 effectively, in this embodiment, the combination of the insulating film 120 and the insulating glue G1 is adopted herein instead, and the insulating film 120 is adapted to attach to and cover at least most of the second electronic components A2, which saves the application time, while the remaining part may be filled with the insulating glue G1.

As shown in FIG. 1, the second electronic components A2 disposed on the periphery of the first electronic component A1 are disposed in different radial directions relative to the first electronic component A1, meaning that these second electronic components A2 have different relative distances with respect to the first electronic components A1. Starting from the retaining wall 150 (i.e., the outer edge 122 of the insulating film 120), the insulating film 120 substantially extends to cover part of the second electronic components A2 with the smallest radial dimension (that is, the second electronic components A2 closest to the first electronic component A1), such that at least part of the second electronic components A2 closest to the first electronic component A2 has been covered by the insulating film 120. Consequently, when the insulating glue G1 is applied continuously, the fixing glue G3 may be marked as the starting point, and the insulating glue G1 is applied until the insulating glue G1 covers the part where the insulating film 120 is adjacent to the inner edge 121. In other words, because of the insulating film 120, the application of the insulating glue G1 may be simplified effectively, dismissing the need to consider limiting the application range of the insulating glue G1 with other technology. Also, as the coating margin of the insulating glue G1 increases, the application process thereof becomes more convenient.

As shown in FIG. 2, after the above components are disposed, the space SP, such as overflow paths L1 and L2 shown in the figure, is formed for the liquid metal 130 to overflow. The substrate 110 and the second electronic components A2 are hence protected from the overflowing liquid metal 130 by the insulating film 120 and the insulating glue G1.

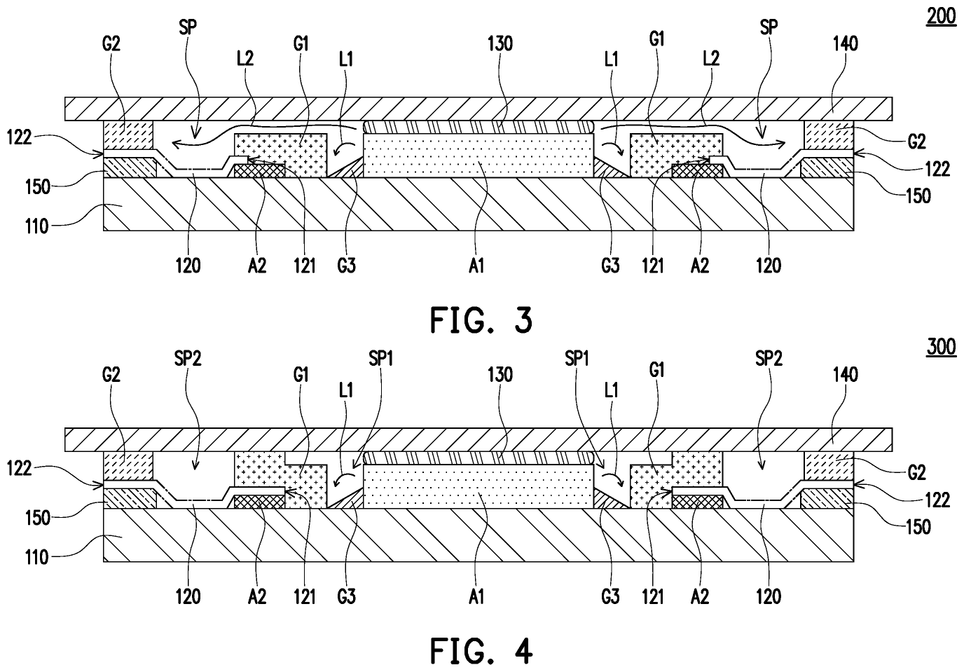

Due to the margin mentioned, the covering state of the insulating film 120 and the second electronic components A2 are not particular limited in this embodiment. Different from the inner edge 121 of the insulating film 120 shown in FIG. 2 that is flush with the side surface of the second electronic components A2, FIG. 3 is a cross-sectional view of an electronic package structure according to another embodiment of the disclosure. In FIG. 3, the inner edge 121 of the insulating film 120 covers only part of the second electronic components A2. What remains unchanged is that the insulating glue G1 in this embodiment also covers part of the insulating film 120 while covering the second electronic components A2, such that the inner edge 121 is pressed by the insulating glue G1 and is prevented from being flipped over by foreign objects or external forces, and the insulating film 120 may be disposed firmly on the substrate 110 and the second electronic components A2.

In another embodiment not shown, the inner edge 121 of the insulating film 120 may also be disposed between the first electronic component A1 and the second electronic components A2 and exceeds the side surface of the second electronic components A2, and the gap between the fixing glue G3 and the second electronic components A2 may be filled by the coating of the insulating glue G1. In yet another embodiment not shown, the insulating glue G1 also has a larger application (range) margin because it partially covers the fixing glue G3. However, the coated insulating glue G1 should not contact or cover the first electronic component A1.

It may be known from FIG. 2, FIG. 3, and the embodiments not shown that, due to the corresponding arrangement of the insulating film 120 and the insulating glue G1, particularly how the insulating glue G1 covers the partial insulating film 120, the electronic package structure of the disclosure has a large margin when configuring the insulating film 120 and the insulating glue G1, which improves the convenience of the process.

FIG. 4 is a cross-sectional view of an electronic package structure according to yet another embodiment of the disclosure. Different from the foregoing embodiment, the insulating glue G1 of this embodiment is in contact with the heat-dissipating plate 140 to further divide the space SP into a first subspace SP1 and a second subspace SP2. The liquid metal 130 is in the first subspace SP1 as shown by the overflow path L1, and the part of the insulating film 120 not covered by the insulating glue G1 is in the second subspace SP2. This makes the electronic package structure of this embodiment suitable for less liquid metal 130, as the structure preliminarily limits the liquid metal 130 that may overflow to the first subspace SP1. This also provides a second layer of protection, namely the insulating film 120 in the second subspace SP2. Even when the liquid metal 130 breaks through the insulating glue G1 and comes into contact with the heat-dissipating plate 140, the insulating film 120 can still provide the protection mechanism as required. It should also be mentioned that the insulating glue G2 of the embodiment shown in FIG. 2 to FIG. 4 may also be modified to be coated on the heat-dissipating plate 140 before being assembled to the insulating film 120. In addition, in the embodiment shown in FIG. 4, the insulating glues G1 and G2 may be coated simultaneously on the heat-dissipating plate 120 and then assembled to the insulating film 120. Similar to the previous embodiment, the insulating glue G1 in this embodiment may also adopt the uncured thermally conductive gel (H-Putty), but still, its thickness needs to be controlled as described above.

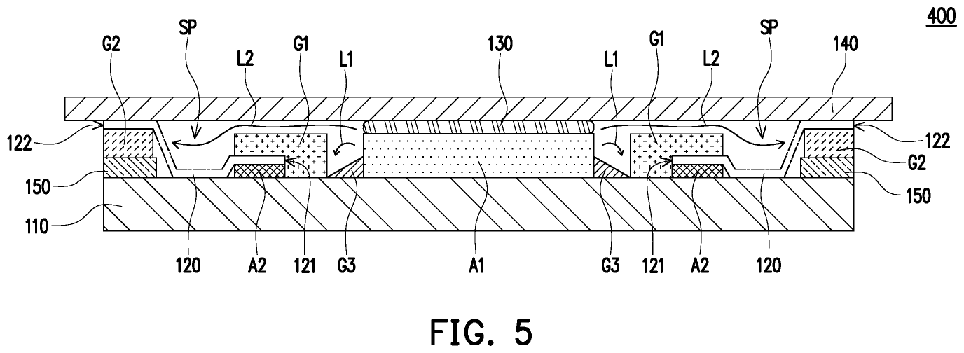

FIG. 5 is a cross-sectional view of an electronic package structure according to still another embodiment of the disclosure. Different from the embodiment shown in FIG. 2, the outer edge 122 of the insulating film 120 in this embodiment is sandwiched between the heat-dissipating plate 140 and the insulating glue G2. As shown in FIG. 2, the insulating glue G2 is applied to the heat-dissipating plate 140 and then cured before the two together cover the substrate 110, the retaining wall 150, and the first electronic component A1. On the contrary, as shown in FIG. 5, the insulating glue G2 is coated on the retaining wall 150 or the insulating film 120, and then the heat-dissipating plate 140 covers onto them. However, no matter which process adopted, a complete protection mechanism is provided for the second electronic components A2 and the substrate 110 to isolate the liquid metal 130 that may overflow.

To sum up, in the electronic package structure according to the above embodiments of the disclosure, an insulating film is disposed on the second electronic component, and then insulating glue is disposed on the substrate, the second electronic component, and the insulating film, such that the insulating glue covers at least part of the insulating film. Therefore, during the assembly process, when the heat-dissipating plate disposed on the first electronic component squeezes the liquid metal therebetween, the insulating glue and the insulating film are able to protect the second electronic component and the substrate by isolating the overflowing liquid metal. In addition to achieving the heat dissipation effect by utilizing the liquid metal effectively, the structure is also able to protect the substrate (and the circuits thereon) and the second electronic component from short-circuiting caused by the liquid metal, providing an effective heat dissipation mechanism and/or a protection mechanism.

In other words, with the combination of the insulating film and the insulating glue, especially how the insulating glue covers the insulating film, the substrate and the second electronic component may be completely covered and isolated from the overflowing liquid metal. This also reduces the difficulty of the application process, and saves time and improves the convenience of the process as the range margin for the insulating film and the insulating glue increases.

What is claimed is:

1. An electronic package structure, comprising:
a substrate;
a first electronic component disposed on the substrate;
at least one second electronic component disposed on the substrate and adjacent to the first electronic component;
an insulating film disposed on the at least one second electronic component and the substrate;
an insulating glue disposed on the at least one second electronic component and the substrate and covering at least part of the insulating film;
a liquid metal disposed on the first electronic component; and
a heat-dissipating plate disposed on the first electronic component and squeezing the liquid metal, wherein the insulating film and the insulating glue prevent the overflowing liquid metal from contacting the at least one second electronic component and the substrate.

2. The electronic package structure according to claim 1, further comprising a retaining wall disposed on the substrate and surrounding the first electronic component, the at least one second electronic component, the insulating film, the insulating glue, and the liquid metal.

3. The electronic package structure according to claim 2, wherein an outer edge of the insulating film is sandwiched between the heat-dissipating plate and the retaining wall.

4. The electronic package structure according to claim 3, further comprising another insulating glue disposed between the retaining wall and the heat-dissipating plate, wherein the outer edge of the insulating film is sandwiched between the another insulating glue and the retaining wall.

5. The electronic package structure according to claim 3, further comprising another insulating glue disposed between the retaining wall and the heat-dissipating plate, wherein the outer edge of the insulating film is sandwiched between the another insulating glue and the heat-dissipating plate.

6. The electronic package structure according to claim 1, wherein an inner edge of the insulating film surrounds the first electronic component and is partially covered by the insulating glue.

7. The electronic package structure according to claim 6, wherein the inner edge of the insulating film is pressed on the at least one second electronic component by the insulating glue.

8. The electronic package structure according to claim 6, wherein the inner edge of the insulating film is disposed between the first electronic component and the at least one second electronic component.

9. The electronic package structure according to claim 1, wherein an inner edge of the insulating film and part of the insulating glue overlap on the at least one second electronic component.

10. The electronic package structure according to claim 1, further comprising a fixing glue disposed on the substrate and at a periphery of the first electronic component to fix the first electronic component on the substrate, wherein a gap exists between the at least one second electronic component and the fixing glue, and part of the insulating glue fills the gap.

11. The electronic package structure according to claim 10, wherein the insulating glue covers part of the fixing glue.

12. The electronic package structure according to claim 1, comprising a plurality of second electronic components disposed on the substrate and at a periphery of the first electronic component, wherein the second electronic components are disposed in different radial directions relative to the first electronic component, and the insulating film covers part of the second electronic components with a smallest radial dimension and rest of the second electronic components.

13. The electronic package structure according to claim 2, wherein the heat-dissipating plate, the substrate, and the retaining wall form a space, and the first electronic component, the at least one second electronic component, the insulating film, the insulating glue, and the liquid metal are within the space.

14. The electronic package structure according to claim 13, wherein the insulating glue is in contact with the heat-dissipating plate and divides the space into a first subspace and a second subspace, the liquid metal is in the first subspace, and a part where the insulating film is not covered by the insulating glue is in the second subspace.

15. The electronic package structure according to claim 1, wherein the first electronic component is a die, and the at least one second electronic component is a capacitor.
